(19) United States
(12) Patent Application Publication
(10) Pub. No.: US 2022/0184743 A1
(43) Pub. Date: Jun. 16, 2022

(54) SUBSTRATE PROCESSING SYSTEM AND SUBSTRATE PROCESSING METHOD

(71) Applicant: Tokyo Electron Limited, Tokyo (JP)

(72) Inventors: Yohei YAMASHITA, Kikuchi-gun, Kumamoto (JP); Hayato TANOUE, Kikuchi-gun, Kumamoto (JP)

(21) Appl. No.: 17/598,339

(22) PCT Filed: Mar. 2, 2020
(86) PCT No.: PCT/JP2020/008696

§ 371 Date: Sep. 27, 2021

(30) Foreign Application Priority Data
Apr. 5, 2019 (JP) 2019-073042

(51) Int. Cl. B23K 26/36; B23K 26/03; B23K 26/08; B23K 26/073; B23K 26/082; B23K 26/06; B23K 26/16

(52) U.S. Cl. CPC B23K 26/36; B23K 26/032; B23K 26/0823; B23K 26/0732; B23K 2101/40; B23K 26/0643; B23K 26/16; B23K 26/0626; B23K 26/0661; B23K 26/082

(57) ABSTRACT

A substrate processing system includes a laser processing apparatus including a holder and a radiation unit, the holder being configured to hold a substrate including a base substrate, an irregularity pattern formed on a main surface of the base substrate, and an irregularity layer formed along the irregularity pattern, the radiation unit being configured to radiate a laser beam to a protrusion of the irregularity layer to flatten the irregularity layer by removing the protrusion in a state that the substrate is held by the holder; a controller configured to control a position of an irradiation point of the laser beam; and a polishing apparatus configured to polish the irregularity layer in which the protrusion is removed with the laser beam to be flattened.

### TECHNICAL FIELD

The various aspects and embodiments described herein pertain generally to a laser processing apparatus, a substrate processing system, a laser processing method, and a substrate processing method.

### BACKGROUND

A manufacturing method for a semiconductor device described in Patent Document 1 includes forming a silicon oxide film on a top surface of a substrate in a required pattern; forming a carbon-containing film on a top surface of the silicon oxide film by a spin-on method; and polishing the carbon-containing film by CMP (Chemical Mechanical Polishing) until the silicon oxide film is exposed. According to this polishing method, a flat surface of the silicon oxide film and a flat surface of the carbon-containing film are formed on a level with each other.

A manufacturing method for a semiconductor device described in Patent Document 2 includes forming an insulating film on a first substrate; forming an insulating film on a second substrate; and bonding the first substrate and the second substrate with the two insulating films therebetween. The insulating films are made of silicon oxide, silicon carbide, silicon carbonitride, or the like.

A manufacturing method for a semiconductor device described in Patent Document 3 (a manufacturing method according to a tenth modification example) includes forming an insulating film on a top surface of a silicon substrate; forming an opening in a part of a top surface of the insulating film; and forming a buried material film in the opening. The buried material film may be, for example, a silicon oxide film. The buried material film is formed on the top surface of the insulating film as well as in the opening, and is then flattened by CMP. Afterwards, the buried material film and a temporarily bonding substrate are bonded.

### PRIOR ART DOCUMENT

Patent Document 1: International Publication No. 2016/143797
Patent Document 2: Japanese Patent Laid-open Publication No. 2018-195656
Patent Document 3: Japanese Patent Laid-open Publication No. 2018-101800

### DISCLOSURE OF THE INVENTION

### Problems to be Solved by the Invention

Exemplary embodiments provide a technique enabling to flatten an irregularity layer in a short time.

### Means for Solving the Problems

In an exemplary embodiment, a laser processing apparatus includes a holder configured to hold a substrate including a base substrate, an irregularity pattern formed on a main surface of the base substrate, and an irregularity layer formed along the irregularity pattern; a radiation unit configured to radiate a laser beam to a protrusion of the irregularity layer to flatten the irregularity layer in a state that the substrate is held by the holder; and a controller configured to control a position of an irradiation point of the laser beam.

### Effect of the Invention

According to the exemplary embodiments, it is possible to flatten the irregularity layer in a short time.

### BRIEF DESCRIPTION OF THE DRAWINGS

FIG. 1 is a plan view illustrating a substrate processing system according to an exemplary embodiment.

FIG. 2A is a cross sectional view illustrating a pattern of an irregularity layer according to the exemplary embodiment.

FIG. 2B is a plan view illustrating the pattern of the irregularity layer according to the exemplary embodiment.

FIG. 3 is a flowchart illustrating a substrate processing method according to the exemplary embodiment.

FIG. 4 is a cross sectional view illustrating a laser processing apparatus according to the exemplary embodiment.

FIG. 5 is a flowchart illustrating a laser processing method according to the exemplary embodiment.

FIG. 6A is a plan view illustrating an area in which an irradiation point of a Galvano scanner can be formed according to the exemplary embodiment.

FIG. 6B is a plan view illustrating an area in which the irradiation point of the Galvano scanner can be formed according to a modification example.

FIG. 7A is a diagram showing an example of an intensity distribution of a laser beam before the laser beam passes through a homogenizer.

FIG. 7B is a diagram showing an example of an intensity distribution of the laser beam after the laser beam passes through the homogenizer.

FIG. 8A is a diagram illustrating a first example method of arranging the irradiation point.

FIG. 8B is a diagram illustrating a second example method of arranging the irradiation point.

FIG. 8C is a diagram illustrating a third example method of arranging the irradiation point.

FIG. 9A is a cross sectional view illustrating a substrate according to a first modification example.

FIG. 9B is a cross sectional view illustrating a substrate according to a second modification example.

FIG. 10A is a cross sectional view illustrating a state of a substrate according to a third modification example before a laser beam is radiated thereto.

FIG. 10B is a cross sectional view illustrating a state of the substrate according to the third modification example after the laser beam is radiated.

### DETAILED DESCRIPTION

Hereinafter, exemplary embodiments of the present disclosure will be described with reference to the accompanying drawings. In the various drawings, same or corresponding parts will be assigned same reference numerals, and redundant description will be omitted. In the present specification, the X-axis direction, the Y-axis direction, and the Z-axis direction are orthogonal to each other. Further, the X-axis direction and the Y-axis direction are horizontal directions, whereas the Z-axis direction is a vertical direction.

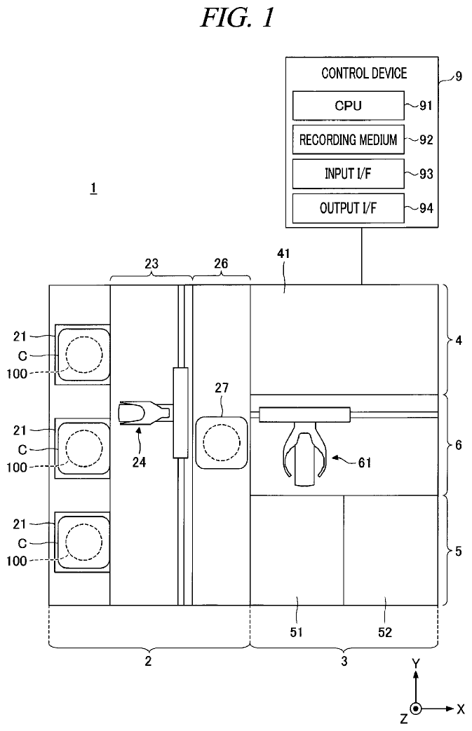

FIG. 1 is a plan view illustrating a substrate processing system according to an exemplary embodiment. A substrate processing system 1 is configured to flatten an irregularity layer of a substrate 100 by a laser beam. Further, the substrate processing system 1 is configured to polish the irregularity layer flattened by the laser beam. Further, before polishing the irregularity layer, the substrate processing system 1 may remove debris produced when the laser beam is radiated.

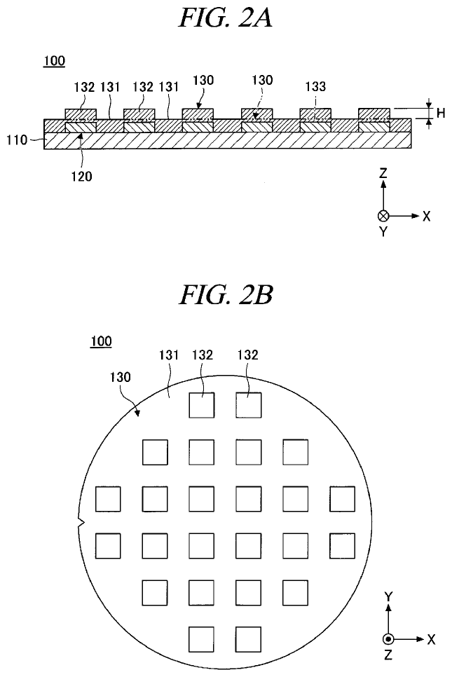

FIG. 2A is a cross sectional view illustrating a pattern of the irregularity layer according to the exemplary embodiment. In FIG. 2A, a dashed double-dotted line indicates an irregularity layer 130 after being flattened. FIG. 2B is a plan view illustrating the pattern of the irregularity layer according to the exemplary embodiment.

The substrate 100 includes, as illustrated in FIG. 2A, a base substrate 110. The base substrate 110 is a semiconductor substrate such as, but not limited to, a silicon wafer or a compound semiconductor wafer. Further, the substrate 100 includes an irregularity pattern 120 formed on a main surface of the base substrate 110. The irregularity pattern 120 is, for example, an irregularity pattern of an electronic circuit.

The substrate 100 includes the irregularity layer 130 formed along the irregularity pattern 120. The irregularity layer 130 may be formed by, for example, a CVD (Chemical Vapor deposition) method, an ALD (Atomic Layer Deposition) method, or a spin-on method.

In the present exemplary embodiment, the irregularity layer 130 is formed by the CVD method or the ALD method. Unlike in the spin-on method, since a solid is precipitated from a gas in the CVD or ALD method, the irregularity pattern 120 can be transferred to the irregularity layer 130. Meanwhile, in the spin-on method, a liquid is coated by spin-coating, and the coated liquid film is solidified by heat treatment. As will be described later in detail, the irregularity layer 130 is formed along the irregularity pattern 120 in the spin-on method as well, having a shape defined by the irregularity pattern 120.

The irregularity layer 130 includes a bottom surface 131 closest to and parallel to the base substrate 110; and a protrusion 132 protruding from the bottom surface 131 in an opposite direction from the base substrate 110. The protrusion 132 has, for example, a rectangle shape, when viewed from the top, as illustrated in FIG. 2B. The rectangle includes a square shape with four equal sides as well as a rectangular shape with two longs sides and two short sides.

The protrusion 132 is plural in number, and the plurality of protrusions 132 are arranged in, for example, a matrix shape. The protrusions 132 may have the same height H. The bottom surface 131 is provided between the neighboring protrusions 132, and the bottom surface 131 is formed in a quadrangle lattice shape. Alternatively, the bottom surface 131 may be not provided between the neighboring protrusions 132, and two kinds of protrusions 132 having different heights H may be arranged one after another.

Since the irregularity layer 130 is flattened by polishing after it is flattened by a laser beam LB as will be described later, the time taken for the polishing can be shortened. If the irregularity layer 130 includes silicon oxide, silicon carbide, silicon nitride, silicon carbonitride, or carbon, these materials are hard and have a slow polishing speed. Thus, the flattening by the laser beam LB is of great significance.

Further, as long as the irregularity layer 130 is flattened by the laser beam LB, it does not need to be flattened by the polishing. The polishing may be performed depending on the purpose of the irregularity layer 130. This is because the level of flatness required varies depending on what the irregularity layer 130 is used for.

As an example, the irregularity layer 130 may be used as a bonding layer. In this case, the irregularity layer 130 is made of silicon oxide, silicon carbide, silicon nitride, or silicon carbonitride. The irregularity layer 130 is a flattened surface and is bonded to a substrate that is different from the substrate 100. Since the surface of the irregularity layer 130 to be bonded to another substrate is previously flattened, the irregularity layer 130 and the substrate can come into firm contact with each other to be firmly bonded to each other.

Furthermore, the irregularity layer 130 may be used as a protective layer. By way of example, the irregularity layer 130 may be inverted upside down after being flattened, and then attracted to a chuck. In this state, the base substrate 110 is ground by a whetstone or the like. Since the surface of the irregularity layer 130 to be attracted to the chuck is previously flattened, the base substrate 110 can be ground flat.

As depicted in FIG. 1, the substrate processing system 1 includes a carry-in/out station 2, a processing station 3, and a control device 9. The carry-in/out station 2 and the processing station 3 are arranged in this sequence from a negative X-axis side toward a positive X-axis side.

The carry-in/out station 2 includes a plurality of placing tables 21. These placing tables 21 are arranged in a row in the Y-axis direction. A cassette C is placed in each of the plurality of (for example, three) placing tables 21. One of these cassettes C accommodates therein a multiple number of substrates 100 before being processed. Another cassette C accommodates therein a multiple number of substrates 100 after being processed. The other cassette C accommodates therein a multiple number of substrates 100 sorted as being abnormal during a processing thereof. The number of the placing tables 21 and the number of the cassettes C are not particularly limited.

Further, the carry-in/out station 2 includes a transfer section 23. The transfer section 23 is disposed next to the plurality of placing tables 21, for example, at a positive X-axis side of the placing tables 21. Further, this transfer section 23 is disposed next to a delivery section 26, for example, at a negative X-axis side of the delivery section 26. The transfer section 23 has a transfer device 24 therein.

The transfer device 24 is equipped with a holding mechanism configured to hold the substrates 100. The holding mechanism is movable in horizontal directions (both X-axis and Y-axis directions) and a vertical direction and pivotable around a vertical axis. The transfer device 24 transfers the substrates 100 between the cassettes C placed in the placing tables 21 and the delivery section 26.

Further, the carry-in/out station 2 is equipped with the delivery section 26. The delivery section 26 is disposed next to the transfer section 23, for example, at a positive X-axis side of the transfer section 23. Further, this delivery section 26 is disposed next to the processing station 3, for example, at a negative X-axis side of the processing station 3. The delivery section 26 has a transition device 27. The transition device 27 accommodates therein the substrates 100 temporarily. The transition device 27 may be plural in number, and the plurality of transition devices 27 may be stacked in the vertical direction. The layout and the number of the transition device 27 are not particularly limited.

The processing station 3 is equipped with a first processing block 4, a second processing block 5, and a transfer block 6. The first processing block 4 is disposed next to the transfer block 6, for example, at a positive Y-axis direction of the transfer block 6. The second processing block 5 is disposed next to the transfer block 6, for example, at a negative Y-axis side of the transfer block 6.

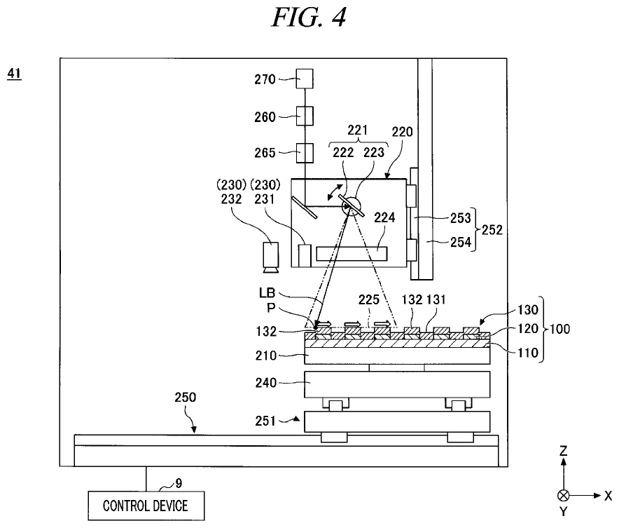

The first processing block 4 includes, for example, a laser processing apparatus 41. The laser processing apparatus 41 forms an irradiation point P of the laser beam LB on the protrusion 132 of the irregularity layer 130, as illustrated in FIG. 4. The laser beam LB is configured to be absorbed in the irregularity layer 130. If the irregularity layer 130 contains carbon, one having a wavelength of, e.g., 190 nm is used as the laser beam LB. If the irregularity layer 130 contains silicon oxide, on the other hand, one having a wavelength of, e.g., 9300 nm is used as the laser beam LB. If the protrusion 132 absorbs the laser beam LB, the protrusion 132 is changed from a solid state to a gas state to be scattered, or scattered while maintaining the solid state. As a result, the protrusion 132 is removed. A flat surface 133 of the same height as the bottom surface 131 is formed at the position of the removed protrusion 132, as indicated by a dashed double-dotted line in FIG. 2A. As a result, the irregularity layer 130 is flattened.

The second processing block 5 has, for example, a debris removing apparatus 51 and a polishing apparatus 52. The debris removing apparatus 51 is configured to remove debris produced when the laser beam LB is radiated. The debris is a material scattered from the irradiation point P. The polishing apparatus 52 is configured to polish the irregularity layer 130 after the irregularity layer 130 is flattened by the laser beam LB. The polishing method may be, for example, CMP (Chemical Mechanical Polishing). The polishing apparatus 52 may polish the irregularity layer 130 until the irregularity pattern 120 is exposed, or such that the irregularity pattern 120 is not exposed. The polishing amount of the polishing apparatus 52 depends on what the irregularity layer 130 is to be used for. Before the polishing apparatus 52 polishes the irregularity layer 130, the debris removing apparatus 51 removes the debris. However, the removal of the debris may be performed even if the irregularity layer 130 is not polished. Further, there may be occasions where the removal of the debris is not necessary.

The transfer block 6 is disposed next to the transition device 27, for example, at a positive X-axis side of the transition device 27. The transfer block 6 has a transfer device 61 therein. The transfer device 61 is equipped with a holding mechanism configured to hold the substrate 100. The holding mechanism is movable in the horizontal directions (both X-axis and Y-axis directions) and the vertical direction and pivotable around a vertical axis. The transfer device 61 transfers the substrates 100 to/from the transition device 27, the laser processing apparatus 41, the debris removing apparatus 51 and the polishing apparatus 52 in a preset order.

Further, the layout and the number of the laser processing apparatus 41, the debris removing apparatus 51 and the polishing apparatus 52 are not limited to the example shown in FIG. 1. Some of these apparatuses may be stacked vertically.

The control device 9 may be, for example, a computer, and includes a CPU (Central Processing Unit) 91 and a recording medium 82 such as a memory, as illustrated in FIG. 1. The recording medium 92 stores thereon a program for controlling various processings performed in the substrate processing system 1. The control device 9 allows the CPU 91 to execute the program stored in the recording medium 92, thus controlling an operation of the substrate processing system 1. Further, the control device 9 may be equipped with an input interface 93 and an output interface 94. The control device 9 receives a signal from the outside through the input interface 93 and sends a signal to the outside through the output interface 94.

The program may be recorded in, for example, a computer-readable recording medium and installed from this recording medium to the recording medium 92 of the control device 9. The computer-readable recording medium may be, by way of non-limiting example, a hard disc (HD), a flexible disc (FD), a compact disc (CD), a magneto optical disc (MO), or a memory card. Further, the program may be installed to the recording medium 92 of the control device 9 by being downloaded from a server through Internet.

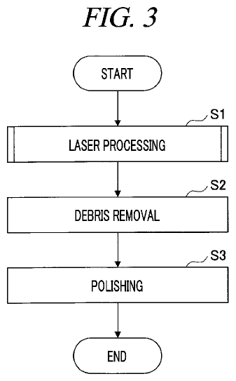

FIG. 3 is a flowchart illustrating a substrate processing method according to the exemplary embodiment. A processing shown in FIG. 3 is performed under the control of the control device 9. First, the transfer device 24 takes out the substrate 100 from the cassette C placed in the placing table 21, and transfers the taken substrate 100 to the transition device 27. Then, the transfer device 61 receives the substrate 100 from the transition device 27, and transfers it to the laser processing apparatus 41.

Then, the laser processing apparatus 41 performs a laser processing on the irregularity layer 130 of the substrate 100 (process S1). To be specific, the laser processing apparatus 41 radiates the laser beam LB to the protrusions 132 of the irregularity layer 130, thus flattening the irregularity layer 130. Thereafter, the transfer device 61 receives the substrate 100 from the laser processing apparatus 41, and transfers it to the debris removing apparatus 51.

Subsequently, the debris removing apparatus 51 removes the debris produced when the laser beam LB is radiated (process S2). The debris removing apparatus 51 is, for example, an etching apparatus configured to remove the debris by etching. The etching is, for example, wet-etching. An etching liquid etches a contact point between the debris and a surface of the irregularity layer 130 after being flattened, thus allowing the debris to be removed and flown away. Since the removal (process S2) of the debris is performed after it is flattened by the laser processing (process S1) and before polishing (process S3) is performed to flatten the irregularity layer 130 more, the debris can be suppressed from being caught between a polishing tool and the substrate 100, so that the level of flatness after the polishing can be improved. If the wet-etching is performed by using a dilute hydrofluoric acid solution, a discolored layer formed in the irregularity layer 130 by the laser processing (process S1) can be removed. Thereafter, the transfer device 61 receives the substrate 100 from the debris removing apparatus 51, and transfers it to the polishing apparatus 52.

Then, the polishing apparatus 52 polishes the irregularity layer 130 flattened by the laser processing (process S1) (process S3). The polishing method may be, for example, CMP (Chemical Mechanical Polishing). Since the polishing (process S3) is performed after the laser processing (process S1), the time taken for the polishing can be reduced.

Thereafter, the transfer device 61 receives the substrate 100 from the polishing apparatus 52, and transfers it to the transition device 27. Then, the transfer device 24 receives the substrate 100 from the transition device 27, and transfers it into the cassette C placed in the placing table 21. Then, the current processing is ended.

Now, a configuration and an operation of the laser processing apparatus 41 will be explained. FIG. 4 is a cross sectional view illustrating the laser processing apparatus according to the exemplary embodiment. The laser processing apparatus 41 is equipped with, for example, a holder 210, a radiation unit 220, a pattern measuring device 230, a rotation driving unit 240, and a movement driving unit 250.

The holder 210 is configured to hold the substrate 100. For example, the holder 210 holds the substrate 100 horizontally from below it such that the irregularity layer 130 of the substrate 100 faces upwards. The holder 210 may be, by way of non-limiting example, a vacuum chuck or an electrostatic chuck.

The radiation unit 220 is configured to radiate the laser beam LB to the protrusion 132 of the irregularity layer 130 in the state that the substrate 100 is held by the holder 210. The irradiation point P of the laser beam LB is formed in the irregularity layer 130. The radiation unit 220 may concentrate the laser beam LB toward the irregularity layer 130, and the irradiation point P is a light condensing point with the highest power density in the present exemplary embodiment. Here, the irradiation point P may not be the condensing point. The protrusion 132 absorbs the laser beam LB to be scattered by being turned into a gas state from a solid state, or scattered while being kept in the solid state. Since the protrusion 132 is removed, the irregularity layer 130 is flattened.

The radiation unit 220 may include, for example, a galvano scanner 221. The galvano scanner 221 is disposed, for example, above the substrate 100 held by the holder 210. With the galvano scanner 221, the irradiation point P in the irregularity layer 130 can be displaced even if the relative position of the galvano scanner 221 and the holder 210 is fixed.

The galvano scanner 221 may include two sets each including a galvano mirror 222 and a galvano motor 223 (only one set is shown in FIG. 4). One galvano motor 223 rotates one galvano mirror 222 to displace the irradiation point P in the X-axis direction. The other galvano motor 223 rotates the other galvano mirror 222 to displace the irradiation point P in the Y-axis direction.

The radiation unit 220 may include a fθ lens 224. The fθ lens 224 forms a focal plane 225 which is orthogonal to the Z-axis direction. While the galvano scanner 221 is displacing the irradiation point P in the X-axis direction or the Y-axis direction, the fθ lens 224 maintains the Z-axis position of the irradiation point P on the focal plane 225, and maintains the shape and the size of the irradiation point P on the focal plane 225. As a result, the irradiation point P of the rectangle shape can be two-dimensionally arranged in the rectangle-shaped protrusion 132 regularly without any gaps.

The pattern measuring device 230 is configured to measure the pattern of the irregularity layer 130 before being flattened. For example, a displacement meter 231 configured to measure the height H of the irregularity layer 130 is used as the pattern measuring device 230. The height H of the irregularity layer 130 is measured with respect to, for example, the bottom surface 131. The displacement meter 231 may be, for example, a laser displacement meter, and measures the height H of the irregularity layer 130 by measuring a distance to the irregularity layer 130. Although the displacement meter 231 is of a non-contact type in the present exemplary embodiment, it may be of a contact type. The displacement meter 231 sends data of the measurement result thereof to the control device 9. The control device 9 measures the height H of the irregularity layer 130 with the displacement meter 231 while moving the displacement meter 231 and the holder 210 relatively in the X-axis and Y-axis directions, thus measuring the pattern of the irregularity layer 130 on a cross section thereof.

Further, a camera 232 configured to image the outline of the protrusion 132 of the irregularity layer 130 may be used as the pattern measuring device 230. The camera 232 images the outline of the protrusion 132 from a direction perpendicular to the bottom surface 131, and sends data of the obtained image to the control device 9. The control device 9 measures the pattern of the irregularity layer 130 in a plan view thereof by performing an image processing on the image received from the camera 232. The pattern of the irregularity layer 130 in the plan view includes the outline of the protrusion 132.

The rotation driving unit 240 is configured to rotate the holder 210. A rotation center line 241 of the holder 210 is parallel to the Z-axis direction. The rotation driving unit 240 includes, for example, a rotation motor. The rotation driving unit 240 rotates the substrate 100 along with the holder 210, allowing the two sides of the protrusion 132 having the rectangle shape in the plan view to be parallel to the X-axis direction and the other two sides of the protrusion 132 to be parallel to the Y-axis direction in the plan view thereof.

The movement driving unit 250 is configured to move the holder 210 and the radiation unit 220 relatively in the X-axis, Y-axis and Z-axis directions. The movement driving unit 250 includes, for example, a first driving unit 251 and a second driving unit 252. The first driving unit 251 moves the holder 210 in the X-axis and Y-axis directions, and the second driving unit 252 moves the radiation unit 220 in the Z-axis direction.

The first driving unit 251 is, by way of non-limiting example, a XY-stage. The second driving unit 252 includes a Z-axis guide 253 and a driving source 254 such as a motor configured to move the radiation unit 220 along the Z-axis guide 253. Since the radiation unit 220 does not move in the X-axis and Y-axis directions, the laser beam LB from the Z-axis direction can always be received at the same point. The radiation unit 220 is moved in the Z-axis direction so that the focal plane 225 of the fθ lens 224 coincides with the top surface of the protrusion 132. Further, the holder 210 instead of the radiation unit 220 may be moved in the Z-axis direction.

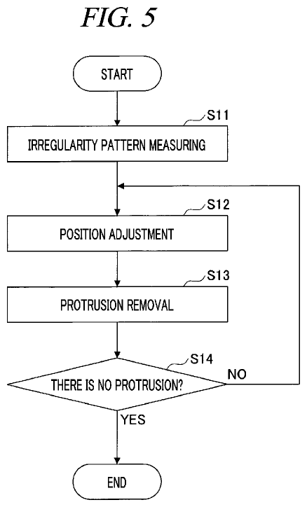

FIG. 5 is a flowchart illustrating a laser processing method according to the exemplary embodiment. The processing shown in FIG. 5 is begun after the laser processing apparatus 41 receives the substrate 100 from the transfer device 61 and the holder 210 attracts and holds the substrate 100.

First, the control device 9 measures the pattern of the irregularity layer 130 with the pattern measuring device 230 (process S11). To elaborate, the control device 9 measures the height of the irregularity layer 130 with the displacement meter 231 while moving the displacement meter 231 and the holder 210 relatively in the X-axis and Y-axis directions, thus measuring the pattern of the irregularity layer 130 on the cross section thereof. Further, the control device 9 images the irregularity layer 130 with the camera 232, and measures the pattern of the irregularity layer 130 in the plan view by performing the image processing on the obtained image.

Then, the control device 9 controls the rotation driving unit 240 and the movement driving unit 250 to perform position adjustment between the holder 210 and the radiation unit 220 (process S12). To elaborate, the control device 9 controls the rotation of the holder 210 based on the outline of the protrusion 132 measured by the camera 232, thus allowing the two sides of the protrusion 132 having the rectangle shape in the plan view to be parallel to the X-axis direction and the other two sides of the protrusion 132 to be parallel to the Y-axis direction. Further, the control device 9 moves the radiation unit 220 in the Z-axis direction to align the height of the irradiation point P with the height of the protrusion 132. The height of the irradiation point P is the height of the focal plane 225. Further, the control device 9 moves the holder 210 in the X-axis and Y-axis directions to overlap a target area of the substrate 100 and an area A where the irradiation point P of the galvano scanner 221 can be formed. The area A is a region in which the irradiation point P can be moved by the rotation of the galvano mirror 222.

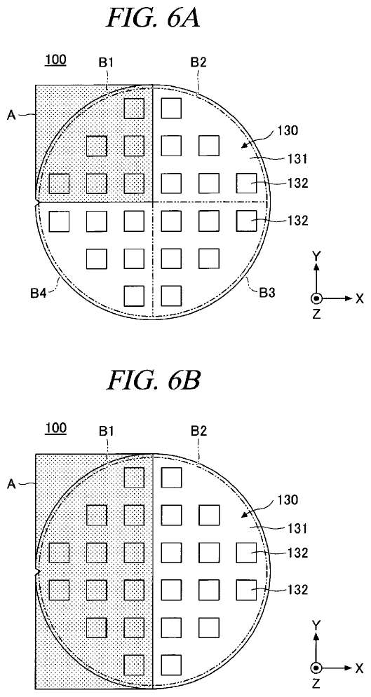

FIG. 6A is a plan view illustrating the region where the irradiation point of the galvano scanner can be formed according to the exemplary embodiment. As depicted in FIG. 6A, the substrate 100 is divided into four areas B1 to B4 in a circumferential direction thereof, for example. Each of the four areas B1 to B4 has a fan shape with a central angle of 90°. Of the four areas B1 to B4, one area (e.g., the area B1) is included in the area A.

Then, the control device 9 removes the protrusion 132 by radiating the laser beam LB to the protrusion 132 (process S13). The control device 9 controls an output W of a light source 270 of the laser beam LB based on the height H of the protrusion 132 measured by the displacement meter 231. The output is set such that the flat surface 133 is formed at the position of the protrusion 132 to be removed to be on a level with the bottom surface 131. The higher the height H of the protrusion 132 is, the higher the output of the light source 270 is set to be. The control device 9 controls the galvano scanner 221 to remove multiple protrusions 132 within the area B1.

Subsequently, the control device 9 checks whether the protrusions 132 have been removed in all of the four areas B1 to B4 (process S14).

If there is any protrusion 132 remaining in one or more of the four areas B1 to B4 (S14, NO), the control device 9 returns to the process S12 to remove the remaining protrusion 132, and performs the process S12 and the subsequent processes again. To elaborate, the control device 9 rotates the holder 210 to allow, among the four areas B1 to B4, the area (for example, the area B2) in which the protrusion 132 remains to overlap with the area A. The control device 9 rotates the holder 210 by 90°×n (n is an integer equal to or larger than 1) to switch the area of the substrate 100 overlapping with the area A. Since the holder 210 is rotated 90°×n (n is an integer equal to or larger than 1), the two sides of the protrusion 132 having the rectangle shape in the plan view become parallel to the X-axis and the other two sides thereof become parallel to the Y-axis. In the present exemplary embodiment, since the substrate 100 is divided into the four areas B1 to B4, the processes S12 and S13 are performed four times.

Meanwhile, if there is left any protrusion 132 in none of the four areas B1 to B4 (S14, YES), the control device 9 ends the current processing. Then, the control device 9 releases the holding of the substrate 100 by the holder 210. Thereafter, the transfer device 61 receives the substrate 100 from the laser processing apparatus 41, and transfers it to the debris removing apparatus 51.

The substrate 100 of the present exemplary embodiment is divided into the four areas B1 to B4 in the circumferential direction thereof, as shown in FIG. 6A. However, the way how to divide the substrate 100 is not particularly limited. For example, the substrate 100 may be divided into two areas B1 and B2 in the circumferential direction, as shown in FIG. 6B. Each of the two areas B1 and B2 is of a semicircular shape with a central angle of 180°. Of the two areas B1 and B2, one area (for example, the area B1) is included in the area A. The control device 9 rotates the holder 210 by 180°×n (n is an integer equal to or larger than 1) to switch the region of the substrate 100 overlapping the area A. Since the substrate 100 shown in FIG. 6B is divided into the two areas B1 and B2, the processes S12 and S13 are performed twice.

The control device 9 controls the position of the irradiation point P by controlling the galvano scanner 221, the rotation driving unit 240 and the movement driving unit 250, as stated above. Further, the control device 9 may control the position of the irradiation point P by controlling only the movement driving unit 250. In such a case, the galvano scanner 221 may be omitted.

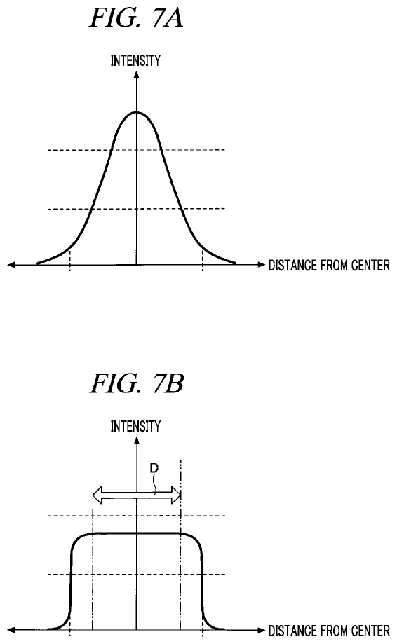

As depicted in FIG. 4, the laser processing apparatus 41 may be equipped with a homogenizer 260. FIG. 7A is a diagram illustrating an example intensity distribution of the laser beam before the laser beam passes through the homogenizer. FIG. 7B is a diagram illustrating an example intensity distribution of the laser beam after the laser beam passes through the homogenizer. The homogenizer 260 changes the intensity distribution of the laser beam LB from the Gaussian distribution shown in FIG. 7A to a top hat distribution shown in FIG. 7B to uniform the intensity distribution of the laser beam LB.

Further, as shown in FIG. 4, the laser processing apparatus 41 may have an aperture 265. The aperture 265 defines the cross sectional shape of the laser beam LB into the rectangle shape. The rectangle shape includes a square shape as well as a rectangular shape. The aperture 265 is a light shielding film having a rectangle-shaped opening. The opening allows the laser beam LB within a range indicated by, for example, an arrow D in FIG. 7B to pass therethrough.

By the homogenizer 260 and the aperture 265, it is possible to form the rectangle-shaped irradiation point P with the uniform intensity distribution. By two-dimensionally arranging this irradiation point P regularly without gaps as will be described later, a total radiation amount J of the laser beam LB per unit area can be uniformed, so that local heating can be suppressed. Thus, it is possible to remove a required portion of the irregularity layer 130 selectively while suppressing damage to the irregularity pattern 120 under the irregularity layer 130. Further, since the intensity distribution varies discontinuously at the outer edge of the irradiation point P, a boundary between the portion of the irregularity layer 130 to be removed and a portion of the irregularity layer 130 to be left can be sharply formed.

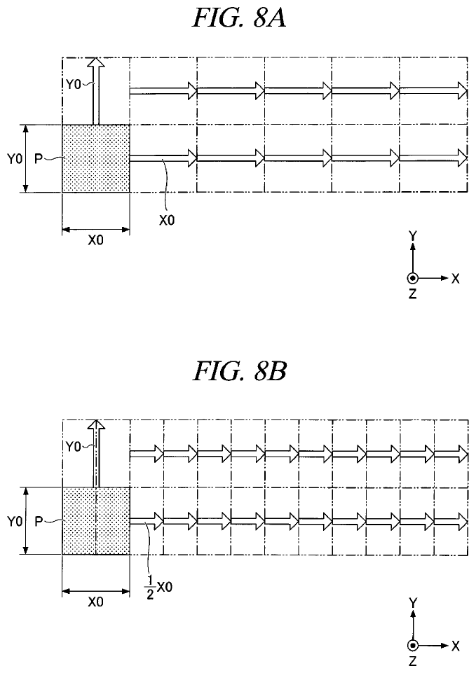

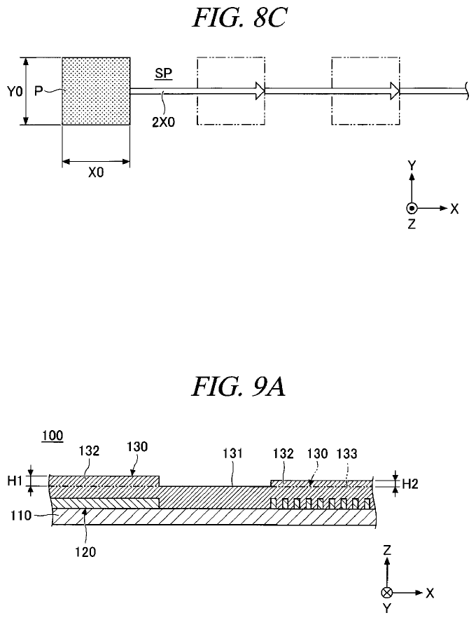

FIG. 8A is a plan view illustrating a first example method of arranging the irradiation point. The irradiation point P is of a rectangle shape with uniform intensity distribution, and two sides of the rectangle shape are parallel to the X-axis and the other two sides thereof are parallel to the Y-axis. A size X0 of the irradiation point P in the X-axis direction may be equal to or different from a size Y0 of the irradiation point P in the Y-axis direction, which is the same as in FIG. 8B and FIG. 8C.

As depicted in FIG. 8A, while oscillating the laser beam LB in a pulse shape, the control device 9 moves the irradiation point P by X0 in the X-axis direction during a pulse-off period, thus allowing the irradiation point P to be arranged in a row without gaps throughout the X-axis side of the protrusion 132. Then, while oscillating the laser beam LB in the pulse shape, the control device 9 repeats moving the irradiation point P by Y0 in the Y-axis direction during the pulse-off period and moving the irradiation point P by X0 in the X-axis direction during the pulse-off period, thus allowing the irradiation point P to be arranged two-dimensionally without gaps on the protrusion 132. According to the method of arranging the irradiation point P shown in FIG. 8A, the total radiation amount of the laser beam LB per unit area can be uniformed, so that the local heating can be suppressed.

FIG. 8B is a plan view illustrating a second example method of arranging the irradiation point. As illustrated in FIG. 8B, while oscillating the laser beam LB in a pulse shape, the control device 9 moves the irradiation point P by X0/2 (half of the X0) in the X-axis direction during a pulse-off period, thus allowing the irradiation point P to be arranged in a row throughout the X-axis side of the protrusion 132 while being overlapped. Then, while oscillating the laser beam LB in the pulse shape, the control device 9 repeats moving the irradiation point P by Y0 in the Y-axis direction during the pulse-off period and moving the irradiation point P by half of the X0 in the X-axis direction during the pulse-off period, thus allowing the irradiation point P to be arranged two-dimensionally without gaps on the protrusion 132. According to the method of arranging the irradiation point P shown in FIG. 8B, the total radiation amount of the laser beam LB per unit area can be uniformed, so that the local heating can be suppressed. Further, while oscillating the laser beam LB in the pulse shape, instead of moving the irradiation point P by Y0 in the Y-axis direction during the pulse-off period, the control device 9 may move the irradiation point P by the half of Y0 in the Y-axis direction during the pulse-off period.

FIG. 8C is a plan view illustrating a third example method of arranging the irradiation point. As illustrated in FIG. 8C, while oscillating the laser beam LB in a pulse shape, the control device 9 moves the irradiation point P by 2X0 (twice the X0) in the X-axis direction during a pulse-off period, thus allowing the irradiation point P to be arranged in a row throughout the X-axis side of the protrusion 132 while forming gaps SP. Then, to fill the gaps SP with the irradiation point P, the control device 9 moves the irradiation point P by 2X0 in the X-axis direction during the pulse-off period while oscillating the laser beam LB in the pulse shape again. Thereafter, while oscillating the laser beam LB in the pulse shape, the control device 9 repeats moving the irradiation point P by Y0 in the Y-axis direction during the pulse-off period, moving the irradiation point P by 2X0 in the X-axis direction during the pulse-off period and, to fill the gaps SP with the irradiation point P, moving the irradiation point P by 2X0 in the X-axis direction during the pulse-off period, thus allowing the irradiation point P to be arranged two-dimensionally without gaps. According to the method of arranging the irradiation point P shown in FIG. 8C, the total radiation amount of the laser beam LB per unit area can be uniformed, so that the local heating can be suppressed.

So far, the laser processing apparatus, the substrate processing system, the laser processing method and the substrate processing method according to the exemplary embodiment have been described. However, it should be noted that the present disclosure is not limited to the above-described exemplary embodiment. Various changes, modifications, replacements, addition, deletion and combinations may be made within the scope of the claims, and all of these are included in the scope of the inventive concept of the present disclosure.

The way how to form the irregularity pattern 120 is not particularly limited as long as it is formed on the main surface of the base substrate 110. By way of example, multiple semiconductor chips formed on a substrate different from the base substrate 110 may be arranged on the main surface of the base substrate 110 at a distance therebetween, and bonded to the base substrate 110 to thereby form the irregularity pattern 120. The multiple semiconductor chips may be arranged in a matrix shape with a gap therebetween.

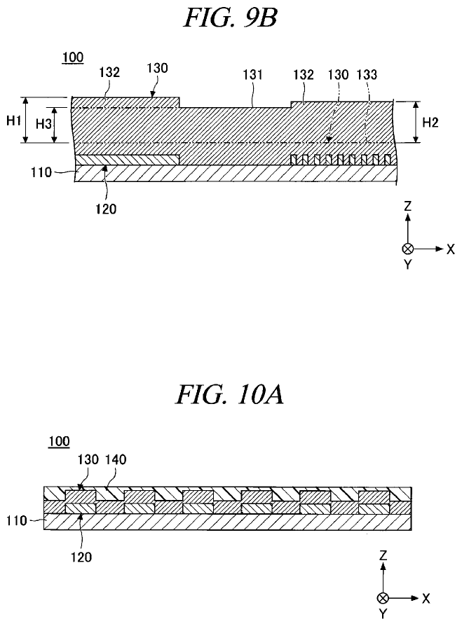

FIG. 9A is a cross sectional view illustrating a substrate according to a first modification example. In FIG. 9A, a dashed double-dotted line indicates the irregularity layer 130 after being flattened. The irregularity layer 130 according to the present modification example is formed by a spin-on method. The spin-on method is a method of coating a liquid by spin-coating and solidifying the coated liquid film by heat treatment. The liquid may contain, for example, carbon. Since the liquid can flow, the height of the liquid film is averaged on the fine irregularity structure, resulting in reduction of the height of the protrusion 132. As a result, there exists multiple protrusions 132 with different heights H1 and H2. The control device 9 controls the output W of the light source 270 of the laser beam LB based on the heights H1 and H2 of the protrusions 132 measured by the displacement meter 231. The output W is set such that the flat surface 133 is formed at the position of the protrusion 132 to be removed to be on a level with the bottom surface 131.

FIG. 9B is a cross sectional view illustrating a substrate according to a second modification example. In FIG. 9B, a dashed double-dotted line indicates the irregularity layer 130 after being flattened. The irregularity layer 130 of the present modification example is formed by the spin-on method, the same as the irregularity layer 130 of the first modification example, but is formed to be thicker than the irregularity layer 130 of the first modification example. The control device 9 forms the irradiation point P on the bottom surface 131 as well as on the protrusions 132. That is, the control device 9 radiates the laser beam LB onto the entire top surface of the irregularity layer 130. The control device 9 controls the output W of the light source 270 of the laser beam LB based on the heights H1 and H2 of the protrusions 132 and a height H3 of the bottom surface 131 measured by the displacement meter 231. In this case, the heights H1 and H2 of the protrusions 132 and the height H3 of the bottom surface 131 are measured with respect to the flat surface 133 of the irregularity layer 130 after being flattened. The output of the light source 270 is set such that the entire irregularity layer 130 is flattened and the thickness of the irregularity layer 130 is uniform. Further, the height H3 of the bottom surface 131 depends on the coating amount of the liquid forming the irregularity layer 130.

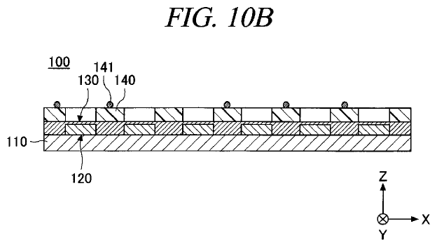

FIG. 10A is a cross sectional view illustrating a state of the substrate according to the third modification example before the laser beam is radiated thereto. FIG. 10B is a cross sectional view illustrating a state of the substrate according to the third modification example after the laser beam is radiated thereto. The substrate 100 according to the present modification example further includes a water-soluble protective layer 140 in addition to the base substrate 110, the irregularity pattern 120 and the irregularity layer 130. The water-soluble protective layer 140 is formed on a surface of the irregularity layer 130 opposite to the base substrate 110 to protect the irregularity layer 130 from the debris 141 produced by the radiation of the laser beam LB. The water-soluble protective layer 140 is made of a water-soluble resin or the like. In this case, the debris removing apparatus 51 is configured as a cleaning apparatus in which the water-soluble protective layer 140 is dissolved in water to be removed and the debris 141 is removed.

The present application claims priority to Japanese Patent Application No. 2019-073042, field on Apr. 5, 2019, which application is hereby incorporated by reference in their entirety.

### EXPLANATION OF CODES

1: Substrate processing system
9: Control device (controller)
41: Laser processing apparatus
51: Debris removing apparatus
52: Polishing apparatus
100: Substrate
110: Base substrate
120: Irregularity pattern
130: Irregularity layer
140: Water-soluble protective layer
210: Holder
220: Radiation unit
221: Galvano scanner
230: Pattern measuring device
240: Rotation driving unit
250: Movement driving unit

1. A substrate processing system, comprising:
a laser processing apparatus including a holder and a radiation unit, the holder being configured to hold a substrate including a base substrate, an irregularity pattern formed on a main surface of the base substrate, and an irregularity layer formed along the irregularity pattern, the radiation unit being configured to radiate a laser beam to a protrusion of the irregularity layer to flatten the irregularity layer by removing the protrusion in a state that the substrate is held by the holder;
a controller configured to control a position of an irradiation point of the laser beam; and
a polishing apparatus configured to polish the irregularity layer in which the protrusion is removed with the laser beam to be flattened.

2. The substrate processing system of claim 1,
wherein the irregularity layer contains silicon oxide, silicon carbide, silicon nitride, silicon carbonitride, or carbon.

3. The substrate processing system of claim 1,
wherein the laser processing apparatus includes a displacement meter configured to measure a height of the irregularity layer before removing the protrusion with the laser beam, and
the controller controls an output of a light source of the laser beam based on a height of the protrusion measured by the displacement meter.

4. (canceled)

5. The substrate processing system of claim 1,
wherein the laser processing apparatus includes a camera configured to image the irregularity layer before the protrusion is removed with the laser beam; and a rotation driving unit configured to rotate the holder,
the radiation unit of the laser processing apparatus includes a homogenizer configured to uniform an intensity distribution of the laser beam; an aperture configured to form a cross sectional shape of the laser beam into a rectangle shape; and a galvano scanner configured to displace the irradiation point in the irregularity layer, and
the controller rotates the holder based on an outline of the protrusion imaged by the camera and removes the protrusion within each area of the substrate overlapping with an area where the irradiation point of the galvano scanner is allowed to be formed, and then, switches the area of the substrate by rotating the substrate.

6. (canceled)

7. (canceled)

8. (canceled)

9. (canceled)

10. The substrate processing system of claim 1, further comprising:
a debris removing apparatus configured to remove, before the substrate is carried into the polishing apparatus, debris which is produced on the irregularity layer in which the protrusion is removed to be flattened; and
a transfer device configured to transfer the substrate between the laser processing apparatus, the polishing apparatus and the debris removing apparatus.

11. (canceled)

12. The substrate processing system of claim 10,
wherein a water-soluble protective layer is formed on a surface of the irregularity layer opposite to the base substrate to protect the irregularity layer from the debris, and
the debris removing apparatus is a cleaning apparatus configured to remove the water-soluble protective layer by dissolving the water-soluble protective layer in water.

13. A substrate processing method, comprising:
holding, with a holder, a substrate including a base substrate, an irregularity pattern formed on a main surface of the base substrate, and an irregularity layer formed along the irregularity pattern;
flattening the irregularity layer by radiating a laser beam to a protrusion of the irregularity layer, controlling a position of an irradiation point of the laser beam and removing the protrusion in a state that the substrate is held by the holder; and
polishing, by a polishing apparatus, the irregularity layer in which the protrusion is removed with the laser beam to be flattened.

14. The substrate processing method of claim 13, further comprising:
measuring a height of the irregularity layer before the protrusion is removed with the laser beam; and
controlling an output of a light source of the laser beam based on a height of the protrusion, which is measured by the measuring of the height of the irregularity layer.

15. The substrate processing method of claim 13, further comprising:
uniforming an intensity distribution of the laser beam with a homogenizer;
forming a cross-sectional shape of the laser beam into a rectangle shape by an aperture;
displacing the irradiation point in the irregularity layer by a galvano scanner;
imaging the irregularity layer before the protrusion is removed with the laser beam; and
rotating the holder based on an outline of the imaged protrusion and removing the protrusion within each area of the substrate overlapping with an area where the irradiation point of the galvano scanner is allowed to be formed, and then, switching the area of the substrate by rotating the substrate.

16. (canceled)

17. (canceled)

18. (canceled)

19. (canceled)

20. The substrate processing method of claim 13, further comprising:
removing, before carrying the substrate into the polishing apparatus, debris produced on the irregularity layer in which the protrusion is removed to be flattened.

21. The substrate processing method of claim 20,
wherein a water-soluble protective layer is formed on a surface of the irregularity layer opposite to the base substrate to protect the irregularity layer from the debris, and
the removing of the debris includes removing the water-soluble protective layer by dissolving the water-soluble protective layer in water.

22. The substrate processing method of claim 13,
wherein the irregularity layer contains silicon oxide, silicon carbide, silicon nitride, silicon carbonitride, or carbon.
